(19) United States
(12) Patent Application Publication
(10) Pub. No.: US 2009/0224324 A1
(43) Pub. Date: Sep. 10, 2009

(54) SEMICONDUCTOR DEVICE AND MANUFACTURING METHOD THEREOF

(75) Inventor: NOBUYUKI NAKAMURA, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/396,537

(22) Filed: Mar. 3, 2009

(30) Foreign Application Priority Data
Mar. 5, 2008 (JP) 2008-054762

(51) Int. Cl. H01L 23/525; H01L 21/336

(52) U.S. Cl. 257/355; 438/281; 257/E23.149; 257/E21.409

(57) ABSTRACT

A semiconductor device includes a semiconductor substrate, and an electric fuse element, the electric fuse element including: first impurity-diffused layer regions formed in an active region of the semiconductor substrate; an insulating film formed on the semiconductor substrate between the first impurity-diffused layer regions; and a gate electrode formed on the insulating film, the insulating film including thermal oxide silicon films arranged immediately below both ends of the gate electrode in a gate-length direction thereof, and a high-k film arranged between the thermal oxide silicon films.

### BACKGROUND OF THE INVENTION

1. Field of the Invention

The present invention relates to a semiconductor device including an electric fuse element, and a method of manufacturing the semiconductor device.

Priority is claimed on Japanese Patent Application No. 2008-054762, filed Mar. 5, 2008, the content of which is incorporated herein by reference.

2. Description of Related Art

Conventionally, in a final manufacturing step, circuit connection information of a semiconductor product is changed to obtain a desired circuit operation. The purpose of this is to remedy operational malfunctions caused by problems in the manufacturing step, switch functions of the circuit, and so on.

The following is an example of means of changing circuit connection. A fuse is provided beforehand in a semiconductor product. By inputting a specific signal from the outside, the conductive state of the fuse is changed, and a desired circuit operation is obtained. The fuse used at this time is known as an electric fuse element (sometimes termed an anti-fuse). This fuse is non-conductive in its initial state, and can be changed to a conductive state by responding to a signal inputted from the outside.

Japanese Unexamined Patent Application, First Publication, No. 2007-194486 discloses a technique, employed when fabricating an electric fuse element in a semiconductor device including a MOS transistor, whereby the MOS transistor is used without alteration, and the conductive state is changed according to whether there is breakage in a gate insulating film.

Conventionally, silicon oxide film (SiO₂) is generally used as a gate insulating film in a MOS transistor. Recently, to accommodate the enhanced characteristics that are demanded of MOS transistors (leakage current, on current, and the like), insulating films having a higher dielectric constant than silicon oxide are being developed. These high-dielectric-constant films are known as high-k insulating films.

While oxide-type insulating films including hafnium (Hf) or zirconium (Zr) are specific examples of high-k insulating films, many other types of film can also be used.

An electric fuse is sometimes formed by a process similar to that of the MOS transistor. Accordingly, a high-k film is sometimes used as an insulating film for the electric fuse.

A conventional electric fuse element will be explained with reference to the drawings.

FIG. 16 is a vertical cross-sectional view showing a conventional electric fuse element. Element isolation regions S are constituted by buried insulating films 52 and 52, and are provided in a p-type silicon (Si) substrate 51. An active region K is partitioned by these element isolation regions S. Impurity-diffused layer regions 55 and 55 are formed in the active region K. The impurity-diffused layer regions 55 and 55 are n-type diffusion layer regions formed by introducing impurities such as phosphorus.

A gate electrode for fuse 54 is formed on the silicon substrate 51 between the impurity-diffused layer regions 55 and 55, with an insulating film for fuse 53 therebetween. A high-k film is used as the insulating film for fuse 53. The high-k film is generally grown by chemical vapor deposition (CVD) (see for example Japanese Unexamined Patent Applications, First Publication No. 2007-251204).

Subsequently, an operating method of this conventional electric fuse element will be explained.

To determine the conductive state of the electric fuse element, the silicon substrate 51 and the impurity-diffused layer regions 55 are both maintained at ground potential, and a voltage small enough not to break down the insulating film for fuse 53 is applied to the gate electrode for fuse 54. The flow of gate current in this state is monitored. When the flow of current is greater than a preset reference current value, the state can be determined as conductive. In an initial state, the electric fuse element is in a non-conductive state.

To change the conductive state, the insulating film for fuse 53 is broken down by applying a large voltage between the gate electrode for fuse 54 and the silicon substrate 51, thereby forming a conductive path between the gate electrode for fuse 54, the silicon substrate 51 or the impurity-diffused layer regions 55. As a result, a gate current greater than the reference value in the determining operation consequently flows, and the electric fuse element is determined as being in a conductive state.

We made the following discoveries.

A high-k insulating film grown by a method such as CVD deposition contains a great many dangling bonds of atoms and traps. This complicates the mechanism for breaking down the insulation of the high-k insulating film. As a result, the operation of breaking down the insulation is unstable, and the value of the gate current that flows after the operation of breaking down the insulation varies considerably.

Consequently, when an electric fuse element is configured using a MOS transistor including a high-k insulating film, malfunction is likely occur when determining the state of a fuse whose conductive state was changed by breaking down the insulation.

### SUMMARY

In one embodiment, there is provided a semiconductor device that includes a semiconductor substrate, and an electric fuse element, the electric fuse element including: first impurity-diffused layer regions formed in an active region of the semiconductor substrate; an insulating film formed on the semiconductor substrate between the first impurity-diffused layer regions; and a gate electrode formed on the insulating film, the insulating film including thermal oxide silicon films arranged immediately below both ends of the gate electrode in a gate-length direction thereof, and a high-k film arranged between the thermal oxide silicon films.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a cross-sectional view showing an electric fuse element according to a first embodiment of the invention;

FIG. 2 is a cross-sectional view showing an example of a method of manufacturing the electric fuse element according to the first embodiment of the invention.

FIG. 3 is a cross-sectional view showing the example of the method of manufacturing the electric fuse element according to the first embodiment of the invention;

FIG. 4 is a cross-sectional view showing the example of the method of manufacturing the electric fuse element according to the first embodiment of the invention;

FIG. 5 is a cross-sectional view showing the example of the method of manufacturing the electric fuse element according to the first embodiment of the invention;

FIG. 6 is a cross-sectional view showing the example of the method of manufacturing the electric fuse element according to the first embodiment of the invention;

FIG. 7 is a cross-sectional view showing the example of the method of manufacturing the electric fuse element according to the first embodiment of the invention;

FIG. 8 is a cross-sectional view showing a gate electrode vicinity in the electric fuse element according to the first embodiment of the invention;

FIG. 9 is a cross-sectional view showing an example of a method of manufacturing an electric fuse element according to a second embodiment of the invention;

FIG. 10 is a cross-sectional view showing the example of the method of manufacturing the electric fuse element according to the second embodiment of the invention;

FIG. 11 is a cross-sectional view showing the example of the method of manufacturing the electric fuse element according to the second embodiment of the invention.

FIG. 12 is a cross-sectional view showing the example of the method of manufacturing the electric fuse element according to the second embodiment of the invention;

FIG. 13 is a cross-sectional view showing an example of a method of manufacturing an electric fuse element according to a third embodiment of the invention;

FIG. 14 is a cross-sectional view showing the example of the method of manufacturing the electric fuse element according to the third embodiment of the invention;

FIG. 15 is a cross-sectional view showing the example of the method of manufacturing the electric fuse element according to the third embodiment of the invention; and

FIG. 16 is a cross-sectional view showing an example of a conventional electric fuse element.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

An electric fuse element and a semiconductor device according to an embodiment of the invention, and a method of manufacturing them, will be explained with reference to the drawings. Drawings referred to in the following explanation are explanatory diagrams of the semiconductor device of this embodiment and a manufacturing method thereof. The size, thickness, scale and so on of the various parts shown in the diagrams may differ from the dimensional relationships of those parts in the actual electric fuse element, semiconductor device, and a method of manufacturing them.

### First Embodiment

### (Electric Fuse Element)

An electric fuse element according to a first embodiment of the invention will be explained.

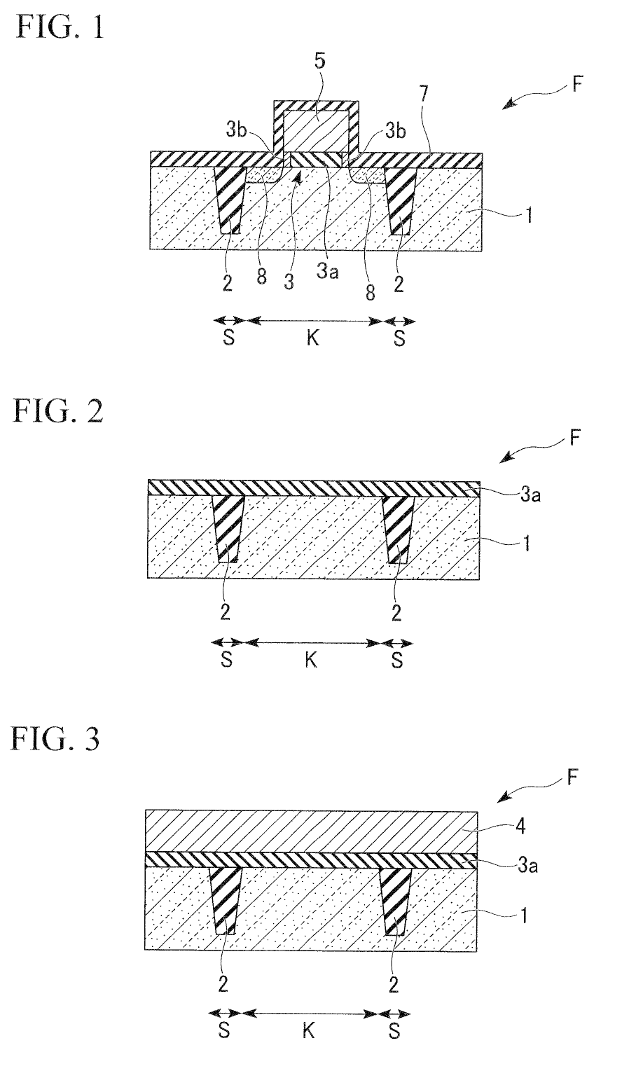

As shown in FIG. 1, an electric fuse element F according to a first embodiment of the invention includes a semiconductor substrate 1, element isolation regions S, an active region K, impurity-diffused layer regions 8, an insulating film for fuse 3, and a gate electrode for fuse 5. The element isolation regions S includes buried insulating films 2 that are buried in the semiconductor substrate 1. The active region K is partitioned by the element isolation regions S. The impurity-diffused layer regions 8 are formed in the active region K. The insulating film for fuse 3 is formed on the semiconductor substrate 1 between the impurity-diffused layer regions 8. The gate electrode for fuse 5 is formed on the insulating film for fuse 3. A thermal oxide silicon film 7 includes a silicon oxide film (SiO₂) formed by thermal oxidation, and covers the gate electrode for fuse 5 and the semiconductor substrate 1.

The insulating film for fuse 3 includes a high-k film 3a, and thermal oxide silicon films 3b and 3b. The high-k film 3a and the thermal oxide silicon films 3b have roughly the same width. The high-k film 3a is formed immediately below a center portion of the gate electrode for fuse 5.

The thermal oxide silicon films 3b are formed immediately below the two ends of the gate electrode for fuse 5 such as to sandwich the high-k film 3a between them. The center portion of the gate electrode for fuse 5 is the center portion in the gate length direction of the gate electrode for fuse 5. The two end portions of the gate electrode for fuse 5 are the ends in the gate-length direction.

The high-k film 3a is, for example, an insulating film with a dielectric constant of more than 3.9. The dielectric constant of the high-k film 3a is only required to be higher than that of thermal oxide film.

An insulating film such as hafnium oxide, tantalum oxide, or lanthanum oxide can be used for the high-k film 3a. The high-k film can be a laminated insulating film having two or more layers of different materials.

The thermal oxide silicon films 3b are formed by thermal oxidization of portions of the semiconductor substrate 1 that are facing the gate width ends of the gate electrode for fuse 5. Unlike silicon oxide films formed by CVD deposition, the thermal oxide silicon films 3b are insulating films with very few dangling bonds of atoms and traps.

The gate electrode for fuse 5 can be a polysilicon film, a metal film, or a laminated body of polysilicon film and metal film.

The silicon oxide film 7 that covers the gate electrode for fuse 5 and the semiconductor substrate 1 is formed at the same time as the thermal oxide silicon films 3b that constitute the insulating film for fuse 3. The silicon oxide film 7 is formed in a single piece with the thermal oxide silicon films 3b. The silicon oxide film 7 is formed from roughly the same material, and has roughly the same width, as the thermal oxide silicon films 3b.

The lateral width of the high-k film 3a is shorter than the width of the gate electrode for fuse 5 in the gate length direction. Immediately below the regions at the two ends of the gate electrode for fuse 5, the thermal oxide silicon films 3b formed by thermal oxidization are filled into the portions between the gate electrode for fuse 5 and the semiconductor substrate 1.

As described above, the insulating film for fuse 3 in the center portion of the gate electrode for fuse 5 is the high-k film 3a. The insulating films for fuse 3 at the two ends of the gate electrode for fuse 5 are the thermal oxide silicon films 3b composed of pure silicon oxide films formed by thermal oxidization. Therefore, when changing the electric fuse element F to a conductive state, portions of the thermal oxide silicon films 3b provided at the ends of the gate electrode for fuse 5 can be selectively broken down to enable conduction. This suppresses variation in the electrical resistance of the electric fuse element F after the conduction operation, and stabilizes the value of the gate current.

### (Manufacturing Method of Electric Fuse Element)

A method of manufacturing the electric fuse element F according to the first embodiment of the invention will be explained.

As shown in FIG. 2, buried insulating films 2 are buried in a semiconductor substrate 1 of p-type silicon using shallow trench isolation (STI) method, thus forming element isolation regions S. Simultaneously, an active region K is formed which is partitioned by the element isolation regions S.

After exposing the surface of the semiconductor substrate 1, CVD method is employed to form a high-k film 3a (e.g. HfSiO₂). Instead of a single-layer film, the high-k film 3a can be a laminated body of multiple films.

Subsequently, as shown in FIG. 3, a conductive layer 4 for a gate electrode is deposited by CVD or sputtering on a top layer of the high-k film 3a. Specifically, a polysilicon layer implanted with an impurity such as phosphorus, a metal layer such as tungsten (W) or titanium (Ti), or a film laminated from these, or such like, can be used as the conductive layer 4.

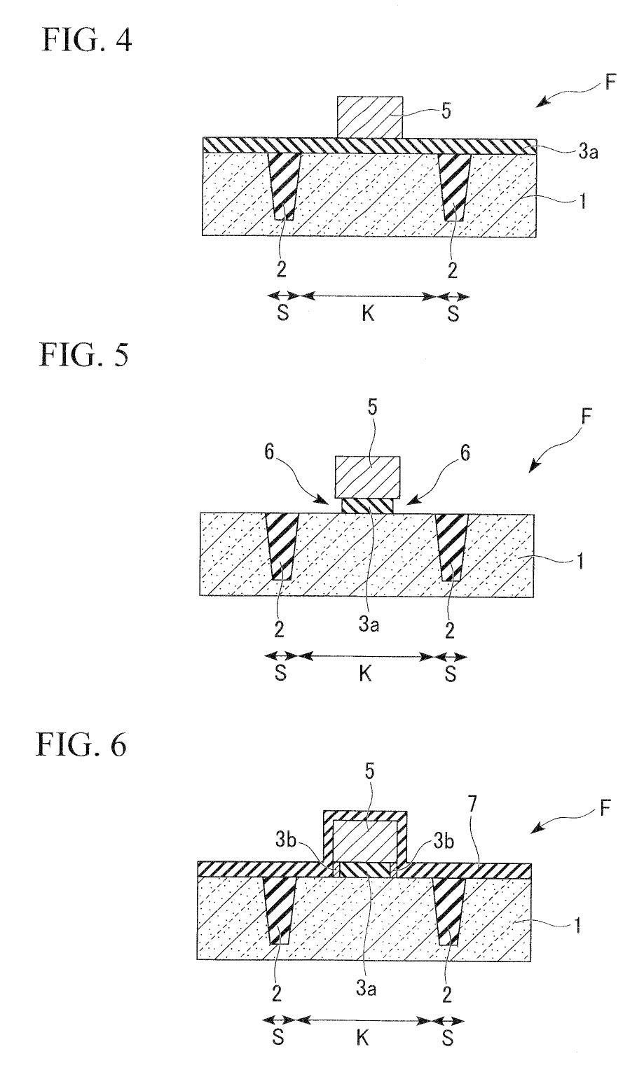

Subsequently, as shown in FIG. 4, the conductive layer 4 is subjected to dry etching using a photoresist film (not shown), forming a gate electrode for fuse 5 that is patterned to a desired flat shape.

Subsequently, as shown in FIG. 5, after patterning the gate electrode for fuse 5, a wet etching process or an isotropic dry etching process is performed, and the high-k film 3a is made to regress inwardly from the ends of the gate electrode for fuse 5. This obtains hollow portions 6 between the ends of the gate electrode for fuse 5 and the semiconductor substrate 1. Simultaneously, high-k film 3a that remained on the semiconductor substrate 1 during dry etching of the gate electrode for fuse 5 is completely removed, and the surface of the semiconductor substrate 1 is exposed.

When using dry etching for regression of a high-k film made from an oxide other than hafnium (Hf), such as an oxide including a material such as tantalum (Ta) or lanthanum (La), it is possible to use dilute hydrofluoric acid (HF) or hydrofluoric acid with ammonium fluoride (NH₄F) added to it (also known as buffered hydrofluoric acid) as the chemical solution. The distance of the regression of the high-k film 3a can be controlled by adjusting the etching time in accordance with characteristics of the desired electric fuse element F.

Subsequently, as shown in FIG. 6, thermal oxidation is performed in an oxidizing atmosphere of 750° C. to 800° C., and a silicon oxide film 7 having a thickness of 1.0 nm to 2.0 nm is formed on the semiconductor substrate 1 and the gate electrode for fuse 5. Since the regression of the high-k film 3a from the ends of the gate electrode for fuse 5 was performed in advance, thermal oxide silicon films 3b of pure silicon oxide films, which are formed by thermal oxidation of the silicon of the semiconductor substrate 1 surface, are formed immediately below the ends of the gate electrode for fuse 5. The hollow portions 6 formed by the gate electrode for fuse 5 and the semiconductor substrate 1 are filled with these pure silicon oxide films 3b. Here, a ‘pure’ insulating film denotes an insulating film which, unlike an insulating film grown by CVD deposition, has few dangling bonds of atoms and traps in the film. While an oxide film of material constituting the gate electrode is formed on the surface of the gate electrode for fuse 5, in FIG. 6, for simplification, this is not shown separately from the silicon oxide film 7 formed on the surface of the semiconductor substrate 1.

Subsequently, ion implantation of an n-type impurity such as phosphorus is performed using the gate electrode for fuse 5 as a mask, forming n-type impurity-diffused layer regions 8 on the semiconductor substrate 1 at both ends of the gate electrode for fuse 5 in its gate length direction. This obtains the structure shown in FIG. 1.

An interlayer insulating film of silicon oxide film or such like is then formed by CVD, and a contact plug for electrode-extraction, a metal wiring layer, and such like are formed, thus completing the electric fuse element F.

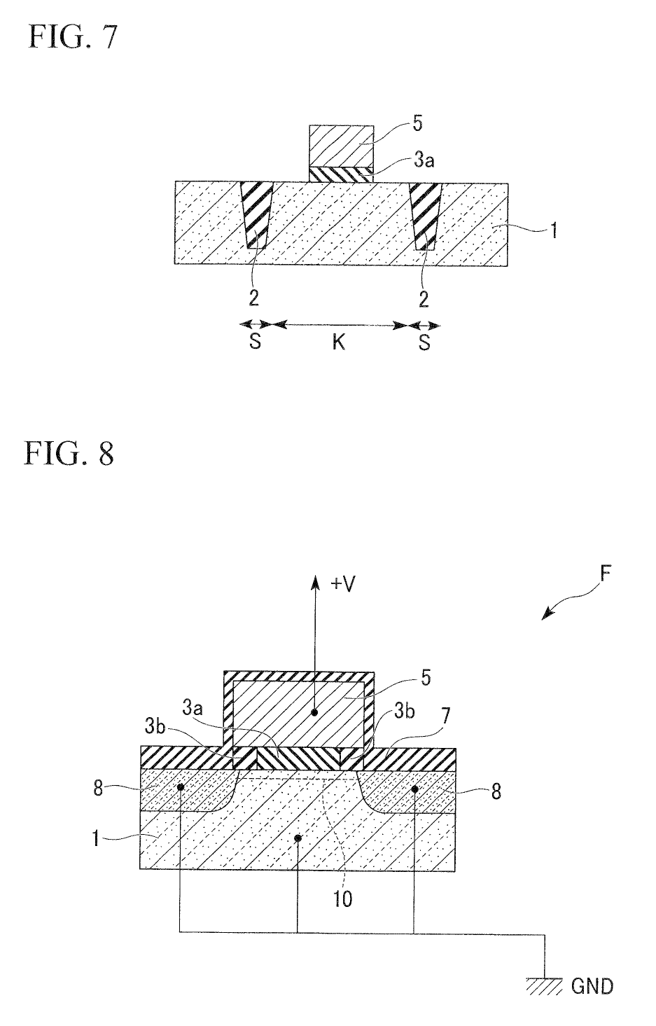

During dry etching of the gate electrode for fuse 5 in the step shown in FIG. 4, dry etching can be performed until the high-k film 3a in regions not covered by the gate electrode for fuse 5 as shown in FIG. 7 is completely removed. In this case, the structure shown in FIG. 5 is obtained by regression of the high-k film 3a at the ends of the gate electrode for fuse 5 by performing wet etching or the like. Subsequent steps are the same as those already described.

### (Operation of Electric Fuse Element F)

An operation of the electric fuse element F according to the first embodiment of the invention will be explained.

FIG. 8 is an enlarged view showing a gate electrode vicinity of the electric fuse element F according to the first embodiment of the invention. Like reference symbols are appended to parts already mentioned.

To determine the conductive state of the electric fuse element F, the semiconductor substrate 1 and the impurity- diffused layer regions 8 are both maintained at ground potential (GND potential), and a voltage small enough not to brake down the high-k film 3a and the thermal oxide silicon films 3b is applied to the gate electrode for fuse 5. The flow of gate current in this state is monitored. When the flow of current is greater than a preset reference current value, the state can be determined as conductive. In an initial state, the electric fuse element F is in a non-conductive state.

The conductive state of the electric fuse element F is changed by the following method. With the semiconductor substrate 1 and the impurity-diffused layer regions 8 at ground potential, a large voltage (+V) is applied to the gate electrode for fuse 5, breaking down the insulation. As a result, a conductive path is formed. At this time, if a positive voltage is applied to the gate electrode for fuse 5, since the semiconductor substrate 1 is a p-type, a depletion layer 10 expands at the surface and functions as a capacitance, thereby alleviating the voltage applied to the high-k film 3a on the semiconductor substrate 1.

On the other hand, since the impurity-diffused layer regions 8 are n-type regions, if a positive voltage is applied to the gate electrode for fuse 5, the surface vicinities of the impurity-diffused layer regions 8 become an accumulation state. Therefore, the voltage value applied to the gate electrode for fuse 5 is applied unaltered to the thermal oxide silicon films 3b on the impurity-diffused layer regions 8. Although it depends on the type of film being used for the high-k film 3a, in comparison with a pure silicon oxide film of the same thickness, while the high-k film 3a is likely to suffer leakage current due to effects of a great many traps and the like in the film, it tends to have greater critical withstand voltage against insulation breakdown.

Therefore, in the electric fuse element F according to the first embodiment of the invention shown in FIG. 8, the thermal oxide silicon films 3b can be selectively broken down. This makes it possible to form a low-resistance conductive path between the gate electrode for fuse 5 and the semiconductor substrate 1, and between the gate electrode for fuse 5 and the impurity-diffused layer regions 8. The thermal oxide silicon films 3b made from pure silicon oxide film can be stably broken down with a high voltage. As a result, the electric fuse element F according to the first embodiment of the invention can suppress variation in the gate current value after forming a conductive path by breaking down the insulation.

There is no particular reference regarding the distance of regression of the high-k film 3a achieved by etching. However, since insulation can be more stably broken down if the thermal oxide silicon films 3b of pure silicon oxide films are increased to the largest possible area, this is considered preferable. As a specific example, if the high-k film 3a is regressed by a distance of approximately one-quarter of the gate width of the gate electrode for fuse 5 in a fuse portion by etching, it will be possible to restrict peeling of the gate electrode for fuse 5 during processing, and in addition, the electric fuse element F according to the first embodiment of the invention will be able to operate stably.

Regarding the operation of the electric fuse element F according to the first embodiment of the inventions the method of applying voltage described above is merely one example, and is not to be considered limitative. For example, the semiconductor substrate 1 and the impurity-diffused layer regions 8 can both be set at negative potential (−1 to −2V). Likewise in this case, a conductive path can be formed stably by insulation breakdown by applying to the gate electrode a voltage which is higher than the potential of the semiconductor substrate 1 and the impurity-diffused layer regions 8. Also, the conductive state of the electric fuse element F can be determined without difficulty by the same method as when the semiconductor substrate 1 and the impurity-diffused layer regions 8 are at ground potential.

The impurity-diffused layer regions 8 can be p-type impurity-diffused layer regions formed by ion implantation of a p-type impurity instead of an n-type impurity. In that case, an n-type well is formed beforehand in the semiconductor substrate 1, and the electric fuse element F is formed in this n-type well. In this case, insulation is preferably broken down by applying a negative voltage to the impurity-diffused layer regions 8.

### Second Embodiment

### (Semiconductor Device H)

There follows an explanation of a semiconductor device according to a second embodiment of the invention in which the electric fuse element F according to the first embodiment and a MOS transistor are both provided on a semiconductor substrate 1.

As shown in FIG. 12, the semiconductor device H of this embodiment constitutes a region A where a MOS transistor is provided and a desired circuit is formed, and a region B where an electric fuse element F is formed.

The MOS transistor T in the region A includes a semiconductor substrate 21, element isolation regions S, an active region K, impurity-diffused layer regions 28, a gate electrode 25, and a thermal oxide silicon film 27. The element isolation region S includes buried insulating film 22 that is buried in the semiconductor substrate 21. The active region K is partitioned by the element isolation regions S. The impurity-diffused layer region 28 is formed in the active region K. The gate electrode 25 is formed on the semiconductor substrate 21 between the impurity-diffused layer regions 28 and 28, with a gate insulating film 23 composed of a high-k film therebetween. The thermal oxide silicon film 27 is formed by thermal oxidation and covers the gate electrode 25 and the semiconductor substrate 21.

As in the first embodiment, in the electric fuse element F in the region B, the lateral width of the high-k film 3a is shorter than the gate length width of the gate electrode for fuse 5. Immediately below the two end portions of the gate electrode for fuse 5 in the gate length direction, thermal oxide silicon films 3b made of silicon oxide film formed by thermal oxidation fill the portions between the gate electrode for fuse 5 and the semiconductor substrate 21. In this embodiment, insulating films having a higher dielectric constant than that of the thermal oxide silicon films 3b (3.9) are treated as high-k insulating films.

With this configuration, an insulating film for fuse 3 in a center portion of the gate electrode for fuse 5 is a high-k film 3a. The insulating films for fuse 3 at the ends of the gate electrode for fuse 5 are thermal oxide silicon films 3b of pure silicon oxide formed by thermal oxidization. Consequently, when changing the electric fuse element F to a conductive state, portions of the thermal oxide silicon films 3b provided at the ends of the gate electrode for fuse 5 can be selectively broken down to enable conduction. This suppresses variation in the electrical resistance of the electric fuse element F after the conduction operation, and stabilizes the value of the gate current. Therefore, the semiconductor device H according to the second embodiment of the present invention including the electric fuse element F can prevent malfunction when determining the fuse state.

### (Method of Manufacturing Semiconductor Device H)

Subsequently, a method of manufacturing the semiconductor device H according to the second embodiment of the invention will be explained.

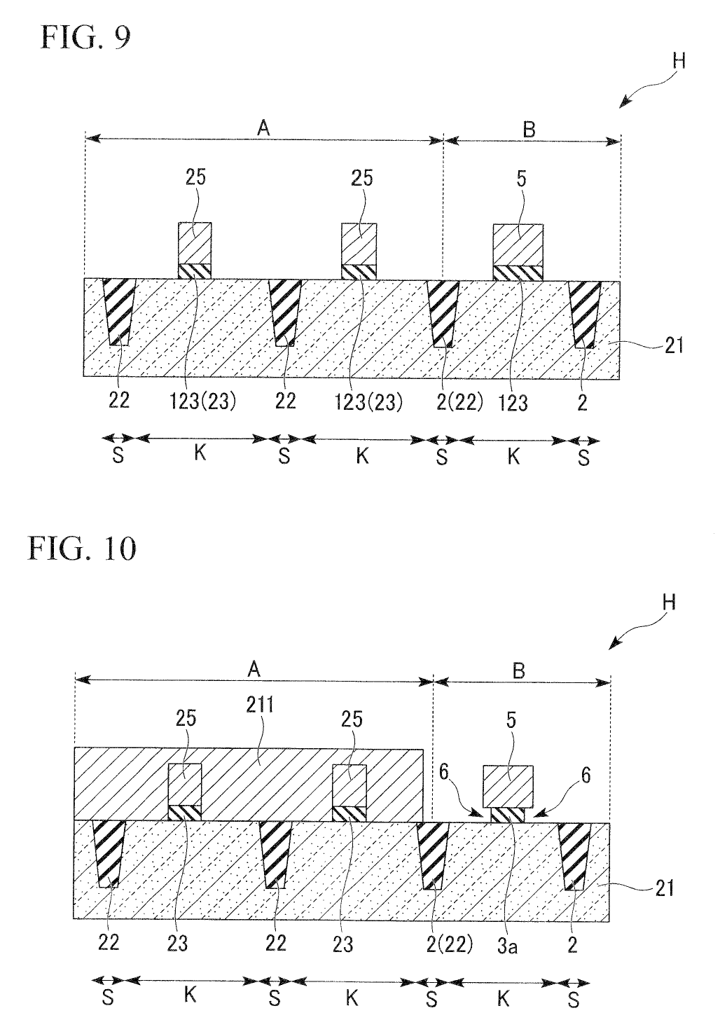

As shown in FIG. 9, buried insulating films 2 and 22 are buried in a semiconductor substrate 21 made of p-type silicon using STI method, forming element isolation regions S. At the same time, active regions K partitioned by the element isolation regions S are formed.

A MOS transistor is provided in a region A on the semiconductor substrate 21, and a desired circuit is formed. An electric fuse element F is provided in a region B on the semiconductor substrate 21.

After laminating a high-k film 123 and a conductive layer composed of polysilicon or the like on the semiconductor substrate 21, a gate electrode 25, a gate electrode for fuse 5, and the high-k film 123 are patterned. As in the example shown in FIG. 4, the dry etching conditions can be controlled such that the high-k film 123 in a region not covered by the gate electrode 25 remains on the semiconductor substrate 21. The high-k film 123 below the gate electrode 25 forms a gate insulating film 23.

Subsequently, as shown in FIG. 10, a photoresist film 211 is used for forming a mask pattern which covers the region A in which the MOS transistor is formed. Then, in the region B, wet etching or isotropic dry etching is performed so that only the high-k film 123 in the region B is made to regress inwardly from both ends of the gate electrode for fuse 5, thus forming hollow portions 6. Buffered hydrofluoric acid is preferably used in wet etching, as this can alleviate damage to the photoresist film 211. Thus the high-k film 3a for fuse insulation is formed.

The photoresist film 211 is then removed.

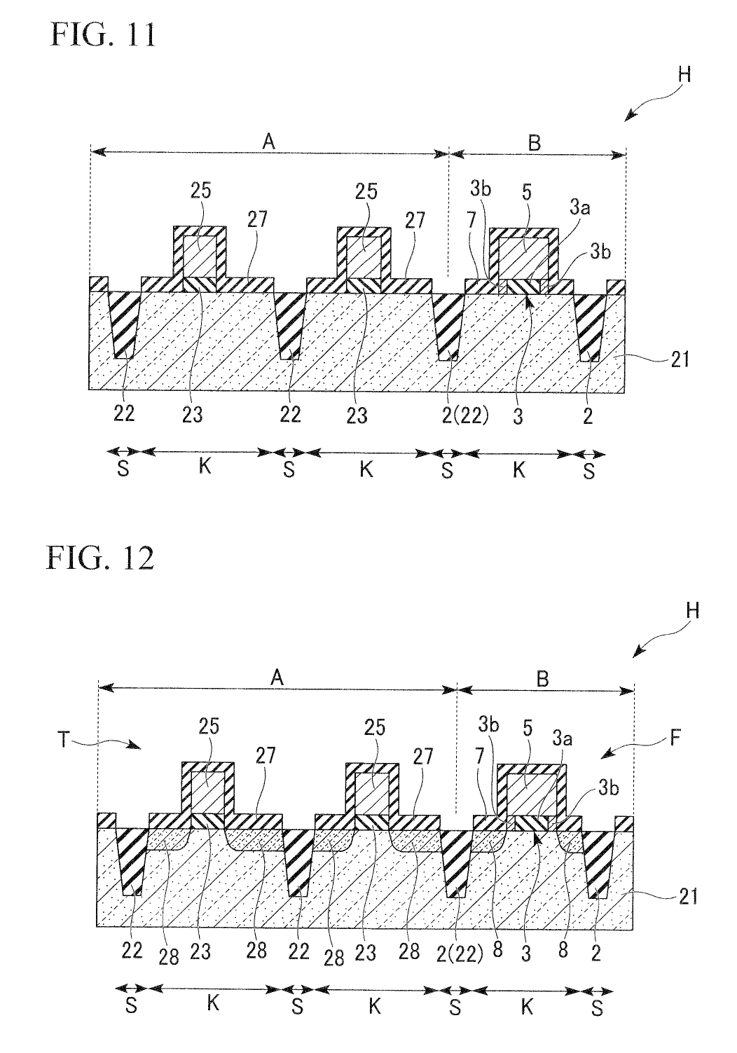

As shown in FIG. 11, by performing a thermal process in a high-temperature oxidizing atmosphere, silicon oxide films 7 and 27 made of pure silicon oxide are formed in a portion where the silicon is exposed on the semiconductor substrate 21. In the region B, the hollow portions 6 at the ends of the gate electrode for fuse 5 are filled with the pure silicon oxide films, and thus form the thermal oxide silicon films 3b.

In the region A, in a region on the semiconductor substrate 21 where the silicon face is exposed, the silicon oxide films 27 made of pure silicon oxide film are formed in the same manner as those in the region B.

Subsequently, n-type impurity-diffused layer regions 28 are formed by ion implantation of an n-type impurity such as phosphorus using the gate electrode 25 and the gate electrode for fuse 5 as masks, obtaining the structure shown in FIG. 12.

Thereafter, an interlayer insulating film of silicon oxide film and the like is formed by CVD, and a contact plug for electrode-extraction, a metal wiring layer, and such like are formed, thus completing the semiconductor device H in which the electric fuse element F and the MOS transistor are provided on the same semiconductor substrate 21.

When the MOS transistor is configured as a CMOS circuit, the following steps should be performed. An n-type well region is formed beforehand in the semiconductor substrate 1. After forming the silicon oxide film 7, a p-type impurity such as boron is implanted in the semiconductor substrate 1 using a photoresist mask, thus forming a MOS transistor including a p-type impurity-diffused layer in the n-type well.

### Third Embodiment

### (Semiconductor Device H1)

A semiconductor device H1 according to a third embodiment of the invention, which combines the electric fuse element with a MOS transistor including a sidewall spacer, will be explained.

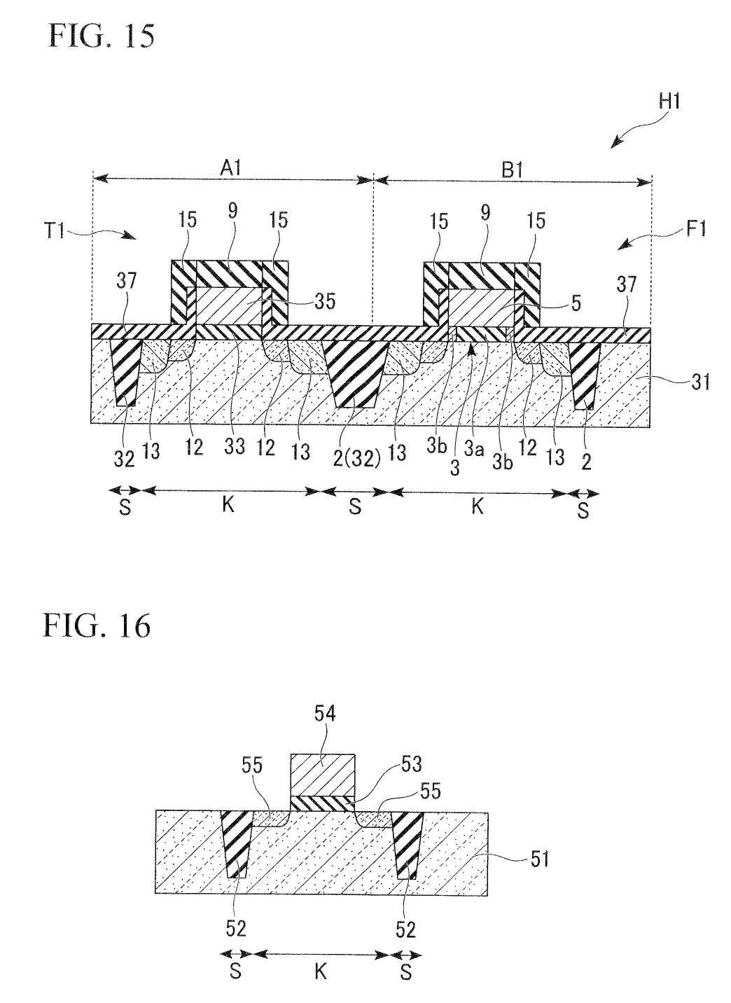

As shown in FIG. 15, the semiconductor device H1 includes a region A1 where a MOS transistor is provided and a desired circuit is formed, and a region B1 where an electric fuse element F is provided.

The MOS transistor T1 in the region A1 includes a semiconductor substrate 31, element isolation regions S, an active region K, first n-type impurity-diffused layer regions 13, a gate electrode 35, second n-type impurity-diffused layer regions 12, a thermal oxide silicon film 37, a cap insulating film 9, and a sidewall spacer 15. The element isolation regions S includes buried insulating films 32 that are buried in the semiconductor substrate 31. The active region K is partitioned by the element isolation regions S. The first n-type impurity-diffused layer regions 13 are formed in the active region K. The gate electrode 35 is formed on the semiconductor substrate 31 between the first n-type impurity-diffused layer regions 13 with a gate insulating film 33 composed of a high-k film therebetween. The second n-type impurity-diffused layer regions 12 are formed near the gate electrode 35. The thermal oxide silicon film 37 is formed by thermal oxidation and covers the semiconductor substrate 31 and side faces of the gate electrode 35. The cap insulating film 9 is formed over the gate electrode 35. The sidewall spacer 15 is formed on side faces of the cap insulating film 9, and side faces of the gate electrode 35 with the thermal oxide silicon film 37 therebetween.

Like the MOS transistor T1, an electric fuse element F1 in the region B1 broadly includes a semiconductor substrate 31, element isolation regions S, an active region K, first n-type impurity-diffused layer regions 12, second n-type impurity-diffused layer regions 13, a gate electrode 5, a thermal oxide silicon film 37, a cap insulating film 9, and a sidewall spacer 15. The element isolation regions S are made from buried insulating films 2 that are buried in the semiconductor substrate 31. The active region K is partitioned by the element isolation regions S. The first n-type impurity-diffused layer regions 12 are formed in the active region K. The second n-type impurity-diffused layer regions 13 are formed at ends of the first n-type impurity-diffused layer regions 12 in the gate length direction. The gate electrode 5 is formed on the semiconductor substrate 31 between the first n-type impurity-diffused layer regions 12 with a high-k film 3a therebetween. The thermal oxide silicon film 37 is formed by thermal oxidation such as to cover side faces of the gate electrode for fuse 5 and the semiconductor substrate 31. The cap insulating film 9 is formed on the gate electrode for fuse 5. The sidewall spacer 15 is formed on side faces of the cap insulating film 9, and side faces of the gate electrode for fuse 5 with the thermal oxide silicon film 37 therebetween.

In the electric fuse element F1, as in the first and second embodiments, the lateral width of the high-k film 3a is smaller than the gate length width of the gate electrode for fuse 5. Immediately below the regions at the ends of the gate electrode for fuse 5, the thermal oxide silicon films 3b made of silicon oxide film formed by thermal oxidization are filled into the portions between the gate electrode for fuse 5 and the semiconductor substrate 31. In this embodiment, insulating films having a higher dielectric constant than the dielectric constant (3.9) of the thermal oxide silicon film 37 are treated as high-k insulating films.

In this configuration, the gate insulating film 3 in a center portion of the gate electrode for fuse 5 in the electric fuse element F1 is the high-k film 3a. The gate insulating films 3 at ends of the gate electrode for fuse 5 are thermal oxide silicon films 3b made of pure silicon oxide formed by thermal oxidization. Consequently, when changing the electric fuse element F1 to a conductive state, portions of the thermal oxide silicon films 3b provided at the ends of the gate electrode for fuse 5 can be selectively broken down to enable conduction. This suppresses variation in the electrical resistance of the electric fuse element F1 after the conduction operation, and stabilizes the value of the gate current. Therefore, the semiconductor device H1 according to the third embodiment of the present invention including the electric fuse element F1 can prevent malfunction when determining the fuse state.

### (Method of Manufacturing Semiconductor Device H1)

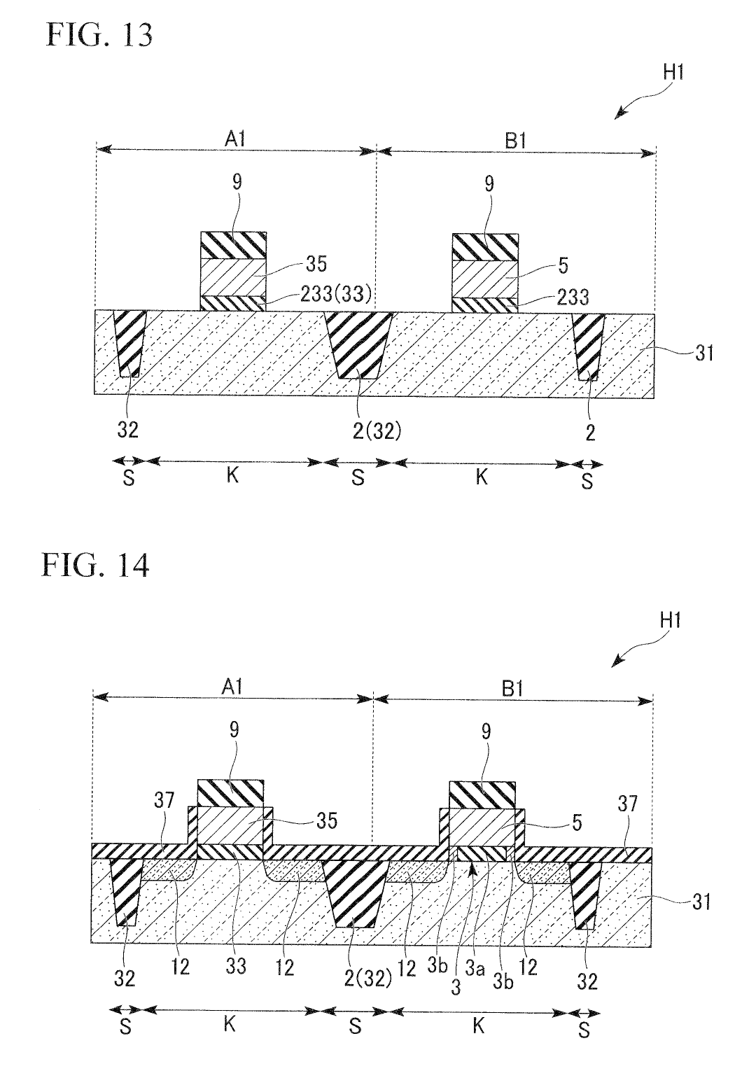

As shown in FIG. 13, buried insulating films 2 and 32 are buried in a semiconductor substrate 31 of p-type silicon using STI method, forming element isolation regions S. An active region K partitioned by the element isolation regions S is formed simultaneously.

A MOS transistor is provided in a region A1 on the semiconductor substrate 31, and a desired circuit is formed. An electric fuse element F1 is provided in a region B1.

After laminating a high-k film 233, a conductive layer 4 of polysilicon, and a cap insulating film 9 for upper surface-protection on the semiconductor substrate 31, patterning of the gate electrode 5, the gate electrode for fuse 35, and the high-k film 233 is performed. A silicon oxide film or a silicon nitride film (Si₃N₄) can be used as the cap insulating film 9.

Then, as shown in FIG. 14, as in the second embodiment, after a photoresist film has been used to completely mask region A1, the high-k film 233 is made to regress by wet etching or the like. As a result, the high-k film 233 in the region B1 is made to regress from the ends of the gate electrode 5. This forms the high-k insulating film for fuse 3a.

A thermal process is then performed in a high-temperature oxidizing atmosphere, whereby a silicon oxide film 37 of pure silicon oxide is formed in a portion where the silicon is exposed on the semiconductor substrate 31. In the region B1, thermal oxide silicon films 3b are formed immediately below both ends of the gate electrode for fuse 5 at the same time as the thermal oxide silicon film 37 is formed. Thereafter, ion implantation of an n-type impurity such as phosphorus is performed using the gate electrode 35, the gate electrode for fuse 5, and the cap insulating film 9 as masks, thereby forming the first n-type impurity-diffused layer regions 12.

Subsequently, a silicon nitride film or the like (not shown) is formed such as to cover the gate electrode 35 and the gate electrode for fuse 5, and a sidewall spacer 15 is then formed by dry etching. Next, second n-type impurity-diffused layer regions 13 are formed by ion implantation of an n-type impurity such as arsenic, obtaining the structure shown in FIG. 15.

Thereafter, an interlayer insulating film of silicon oxide film or the like is formed, and a contact plug for electrode-extraction, a metal wiring layer, and such like are formed, thus completing the semiconductor device H1 according to the third embodiment of the invention in which the electric fuse element F1 and the MOS transistor T1 including the sidewall spacer 15, are provided on the same semiconductor substrate 31.

In FIG. 15, while the sidewall spacer 15 and the second n-type impurity-diffused layer regions 13 are formed in the electric fuse portion of the region B1, they have no particular effect on the operation of the electric fuse element F1 according to this embodiment of the invention.

In addition to the configurations described above here, the structure of the fuse portion can be modified in accordance with the structure of the MOS transistor to be formed on the same semiconductor substrate without departing from the main points of the invention.

It is apparent that the present invention is not limited to the above embodiments, but may be modified and changed without departing from the scope and spirit of the invention.

The invention can be widely applied in a semiconductor device including an electric fuse element, and a semiconductor device including a MOS transistor having a high-k film as its gate insulating film, and so on.

What is claimed is:

1. A semiconductor device comprising a semiconductor substrate, and an electric fuse element, the electric fuse element comprising:
first impurity-diffused layer regions formed in an active region of the semiconductor substrate;
an insulating film formed on the semiconductor substrate between the first impurity-diffused layer regions; and
a gate electrode formed on the insulating film,
the insulating film including thermal oxide silicon films arranged immediately below both ends of the gate electrode in a gate-length direction thereof, and a high-k film arranged between the thermal oxide silicon films.

2. The semiconductor device according to claim 1, wherein the electric fuse element comprises a cap insulating film provided on the gate electrode, and a sidewall spacer formed on sidewalls of the cap insulating film and on a sidewall side of the gate electrode.

3. The semiconductor device according to claim 1, further comprising a MOS transistor, the MOS transistor comprising:
second impurity-diffused layer regions formed in another active region of the semiconductor substrate;
a gate insulating film including a high-k film and formed on the semiconductor substrate between the second impurity-diffused layer regions; and
a gate electrode formed on the gate insulating film.

4. The semiconductor device according to claim 2, further comprising a MOS transistor, the MOS transistor comprising:
second impurity-diffused layer regions formed in another active region of the semiconductor substrate;
a gate insulating film including a high-k film and formed on the semiconductor substrate between the second impurity-diffused layer regions; and
a gate electrode formed on the gate insulating film.

5. The semiconductor device according to claim 1, wherein the thermal oxide silicon film is a pure silicon oxide film formed by thermal oxidation of silicon on a surface of the semiconductor substrate.

6. The semiconductor device according to claim 1, wherein the high-k film has a higher dielectric constant than that of the thermal oxide silicon film.

7. The semiconductor device according to claim 1, wherein the high-k film has a dielectric constant of more than 3.9.

8. A method for manufacturing a semiconductor device comprising manufacturing an electric fuse element, manufacturing the electric fuse element comprising:
forming impurity-diffused layer regions formed in an active region of a semiconductor substrate;
forming a high-k film on the semiconductor substrate between the impurity-diffused layer regions, and forming a gate electrode on the high-k film;
removing parts of the high-k film that are immediately below both ends of the gate electrode in a gate-length direction thereof; and
forming thermal oxide silicon films immediately below the both ends of the gate electrode in the gate-length direction thereof, between the gate electrode and the semiconductor substrate so as to form an insulating film including the high-k film and the thermal oxide silicon films,
the impurity-diffused layer regions being formed in the semiconductor substrate on both sides of the gate electrode in the gate-length direction.

9. The semiconductor device manufacturing method according to claim 8, wherein manufacturing the electric fuse element further comprises:
forming a cap insulating film on the gate electrode; and
forming a sidewall spacer on sidewalls of the cap insulating film and on a sidewall side of the gate electrode.

10. The semiconductor device manufacturing method according to claim 8, wherein the thermal oxide silicon film is formed by thermal oxidation of silicon on a surface of the semiconductor substrate.

11. The semiconductor device manufacturing method according to claim 8, wherein the parts of the high-k film that are immediately below the both ends of the gate electrode in the gate-length direction thereof are removed by etching by a distance of approximately one-quarter of a gate width of the gate electrode.

12. The semiconductor device manufacturing method according to claim 8 further comprising manufacturing a MOS transistor, manufacturing the MOS transistor comprising:
forming second impurity-diffused layer regions in another active region of the semiconductor substrate;
forming a gate insulating film including a high-k film on the semiconductor substrate between the second impurity-diffused layer regions;
forming a gate electrode on the gate insulating film; and
forming a third impurity-diffused layer region that becomes a source and drain on the semiconductor substrate,
wherein the electric fuse element and the MOS transistor are manufactured simultaneously.

13. The semiconductor device manufacturing method according to claim 9 further comprising manufacturing a MOS transistor, manufacturing the MOS transistor comprising:
forming second impurity-diffused layer regions in another active region of the semiconductor substrate;
forming a gate insulating film including a high-k film on the semiconductor substrate between the second impurity-diffused layer regions;
forming a gate electrode on the gate insulating film; and
forming a third impurity-diffused layer region that becomes a source and drain on the semiconductor substrate,
wherein the electric fuse element and the MOS transistor are manufactured simultaneously.

14. The semiconductor device manufacturing method according to claim 12, wherein the parts of the high-k film that are immediately below the both ends of the gate electrode for the fuse element in the gate-length direction thereof are removed by etching by a distance of approximately one-quarter of a gate width of the gate electrode for the fuse element.
